(19) United States
(12) Patent Application Publication
(10) Pub. No.: US 2026/0047345 A1
(43) Pub. Date: Feb. 12, 2026

(54) ASSEMBLIES AND TECHNIQUES FOR ANALYZING NANOSCALE DEVICE OPERATION

(71) Applicant: Regents of the University of Minnesota, Minneapolis, MN (US)

(72) Inventors: Andre Mkhoyan, Minneapolis, MN (US); Hwanhui Yun, Minneapolis, MN (US); Jian-Ping Wang, Shoreview, MN (US); Deyuan Lyu, Minneapolis, MN (US)

(21) Appl. No.: 18/799,520

(22) Filed: Aug. 9, 2024

(51) Int. Cl. H10N 50/10; H10N 50/01

(52) U.S. Cl. CPC H10N 50/10; H10N 50/01

(57) ABSTRACT

An assembly may include a first conductive layer extending along a longitudinal axis, the first conductive layer including a first portion and a second portion laterally spaced from the first portion by an insulating region. The first portion of the first conductive layer is configured to at least partially contact a nanoscale device. A second conductive layer may extend along the longitudinal axis, the second conductive layer extending over the second portion and the insulating region. The second conductive layer is configured to at least partially contact the nanoscale device. At least a portion of the assembly may define an electron-transparent width in a direction transverse to the longitudinal axis. A method may include operating the nanoscale device within the assembly, and imaging the nanoscale device within the assembly during the operating to generate an image of the nanoscale device.

### STATEMENT REGARDING FEDERALLY SPONSORED RESEARCH OR DEVELOPMENT

This invention was made with government support under 70NANB17H041 awarded by the National Institute of Standards and Technology. The government has certain rights in the invention.

### TECHNICAL FIELD

The present disclosure relates to nanoscale devices, and to assemblies and techniques for analyzing nanoscale device operation.

### BACKGROUND

With increasing demands for data storage solutions and advancements in computer science, spintronic magnetic tunnel junction (MTJ)-based magnetic random-access memory (MRAM) devices are emerging as promising alternatives to traditional charge-based memory devices. Spintronics, which leverages the spin state of electrons in electronic devices, has potential in future nano-electronic memory and computing applications due to high speed, energy efficiency, and scalability. An MRAM unit represents a spintronic memory device with an MTJ with two resistance states as its core unit. An MTJ includes an insulating barrier layer sandwiched between two ferromagnetic (FM) layers, a reference layer (RL) and a free layer (FL), whose magnetic alignment determines the tunneling resistance through the MTJ. A parallel magnetic configuration of the two layers produces a lower resistance state, whereas an anti-parallel configuration produces a higher resistance state. While the magnetic configuration can be switched through applied magnetic fields, electric fields, and currents, an alternative switching mechanism is via current-driven switching through a spin transfer-torque mechanism. In perpendicular MTJ (PMTJ) devices, FM layers have a perpendicular magnetic anisotropy (PMA), which offers advantages in switching currents, scalability, and thermal stability. Nanopillar PMTJ unit can be integrated into current semiconductor units, such as complementary metal-oxide semiconductor (CMOS), and offers high scalability.

### SUMMARY

The present disclosure describes nanoscale devices, and assemblies and techniques for analyzing nanoscale device operation.

The applications of nanoscale devices, (e.g., spintronic devices such as MTJ-based devices) benefit from an understanding of differences in internal structure and behavior between different states of operation, including conditions that lead to device breakdown or malfunction, and mechanisms underlying transition between different states and conditions (e.g., from an operational state to a breakdown state). Conventional and analytical transmission electron microscopy (TEM) may be employed for a structural analysis of MTJ devices. For example, details of the crystalline and chemical configurations of the layers and their interfaces may be analyzed with atomic-resolution scanning TEM (STEM). However, TEM studies on MTJ devices may be limited to analyses of an initial structure and a post-run structure, which may not shed light on structural changes during operation of MTJ devices.

Assemblies and techniques according to the present disclosure may be used to investigate structures of nanoscale devices (e.g., MTJ-based devices) during operation. For example, in-situ electrical biasing TEM may be used to analyze nanoscale devices in course of operation (e.g., with application of a voltage and/or current flow). In some examples, an assembly including a nanoscale device has a portion defining an electron-transparent width, with the nanoscale device being functional, which facilitates TEM imaging of the nanoscale device during operation by elemental migration, diffusion, or transport across the nanoscale device. In some examples, assemblies and techniques according to the present disclosure may be used to analyze current-driven magnetic switching performance of nanopillar-structured MTJ devices and study the structural integrity of device structure under different conditions. The structural changes of the MTJ may be evaluated during biasing by adopting STEM-electron energy-loss spectroscopy (EELS), for example, to uncover atomic movements in the layers. Such real-time or near-real time, atomic-level STEM analysis of a fully functional nanoscale device may provide insight into atomistic mechanisms behind structural and compositional changes during device operation, and may be employed for a wide variety of devices.

In some examples, assemblies according to the present disclosure include two conductive layers, with a first conductive layer including an insulating region, and a second conductive layer extending over the insulating region. The first conductive layer and the second conductive layer are both configured to at least partially contact a nanoscale device. The insulating region facilitates spacing or partitioning of the first conductive layer into two electrically-isolated portions, each portion being in electrical communication with a respective terminal of the assembly. The terminals may have a width greater than that of the electron-transparent width, which may promote structural integrity of the assembly while facilitating electrical coupling of the assembly to operate the nanoscale device within the assembly during imaging (e.g., during STEM imaging). The assembly may be facilitated relatively efficiently and rapidly, for example, by depositing the first conductive layer and introducing the insulating region to partition the first conductive layer into the two electrically-isolated portions, compared to deposition separate regions of the first conductive layer. Further, one or more subsequent layers may be deposited over the nanoscale device and the two conductive layers, facilitating ease and efficiency of fabrication. An insulating composition may be deposited in the insulating region, to facilitate deposition of one or more layers (e.g., the second conductive layer extending over the insulating region to contact the nanoscale device) continuously over the insulating region without geometric interruption or disruption that may be caused by an insulating gap. The assembly may include or be fabricated over a device substrate, and one or more components of the assembly (e.g., the nanoscale device) may be fabricated over a temporary substrate and placed on or in the assembly, or the assembly as a whole may be fabricated layer-by-layer.

In some examples according to the present disclosure, an example assembly includes a first conductive layer extending along a longitudinal axis. The first conductive layer may include a first portion and a second portion laterally spaced from the first portion by an insulating region. The first portion of the first conductive layer is configured to at least partially contact a nanoscale device. A second conductive layer may extend along the longitudinal axis. The second conductive layer may extend over the second portion and the insulating region. The second conductive layer is configured to at least partially contact the nanoscale device. At least a portion of the assembly may define an electron-transparent width in a direction transverse to the longitudinal axis.

In some examples according to the present disclosure, an example technique includes forming a first conductive layer extending along a longitudinal axis. The first conductive layer may include a first portion and a second portion laterally spaced from the first portion by an insulating region. The first portion of the first conductive layer at least partially contacts a nanoscale device. The technique may further include forming a second conductive layer extending along the longitudinal axis. The second conductive layer may extend over the second portion and the insulating region. The second conductive layer may at least partially contact the nanoscale device. At least a portion of the assembly may define an electron-transparent width in a direction transverse to the longitudinal axis.

In some examples according to the present disclosure, an example technique includes operating a nanoscale device within an assembly. The assembly may include a first conductive layer extending along a longitudinal axis. The first conductive layer may include a first portion and a second portion laterally spaced from the first portion by an insulating region. A second conductive layer may extend along the longitudinal axis. The second conductive layer may extend over the second portion and the insulating region. The nanoscale device may at least partially contact the first portion of the first conductive layer and at least partially contact the second conductive layer. At least a portion of the assembly may define an electron-transparent width in a direction transverse to the longitudinal axis. The technique may further include imaging the nanoscale device within the assembly during the operating to generate an image of the nanoscale device.

The details of one or more examples of the techniques of this disclosure are set forth in the accompanying drawings and the description below. Other features, objects, and advantages of the techniques will be apparent from the description and drawings, and from the claims.

### BRIEF DESCRIPTION OF THE DRAWINGS

The summary, as well as the following detailed description, is further understood when read in conjunction with the appended drawings. For the purpose of illustrating the disclosure, examples are shown in the drawings; however, the disclosure is not limited to the specific techniques, compositions, and devices disclosed. In addition, the drawings are not necessarily drawn to scale.

FIG. 1 is a conceptual diagram illustrating a perspective view of an assembly including a nanoscale device, a first conductive layer, and a second conductive layer.

FIG. 2 is a conceptual diagram illustrating a side view of an example nanoscale device including a magnetic tunnel junction.

FIG. 3A is a conceptual diagram illustrating a top view of an assembly in a first stage of formation including a nanoscale device on a first conductive layer.

FIG. 3B is a conceptual diagram illustrating a side view of the assembly of FIG. 3A along line S-S.

FIG. 4A is a conceptual diagram illustrating a top view of the assembly of FIG. 3A in a second stage of formation further including an insulating region.

FIG. 4B is a conceptual diagram illustrating a side view of the assembly of FIG. 4A.

FIG. 5A is a conceptual diagram illustrating a top view of the assembly of FIG. 4A in a third stage of formation further including an insulating composition in the insulating region.

FIG. 5B is a conceptual diagram illustrating a side view of the assembly of FIG. 5A.

FIG. 6A is a conceptual diagram illustrating a top view of the assembly of FIG. 5A in a fourth stage of formation further including a second conductive layer.

FIG. 6B is a conceptual diagram illustrating a side view of the assembly of FIG. 6A.

FIG. 7A is a conceptual diagram illustrating a top view of the assembly of FIG. 6A in a fifth stage of formation further including a protective layer.

FIG. 7B is a conceptual diagram illustrating a side view of the assembly of FIG. 7A.

FIG. 8A is a conceptual diagram illustrating a top view of the assembly of FIG. 7A in a sixth stage of formation further including a third conductive layer.

FIG. 8B is a conceptual diagram illustrating a side view of the assembly of FIG. 8A.

FIG. 9A is a conceptual diagram illustrating a top view of the assembly of FIG. 8A trimmed in a seventh stage of formation.

FIG. 9B is a conceptual diagram illustrating a perspective view of the assembly of FIG. 9A.

FIG. 10A is a conceptual diagram illustrating a perspective view of the assembly of FIG. 9A in an eighth stage of formation further cut to define an electron-transparent width.

FIG. 10B is a conceptual diagram illustrating a top view of the assembly of FIG. 10A.

FIG. 11 is a conceptual block diagram illustrating an example technique for forming an assembly including a nanoscale device.

FIG. 12 is a conceptual block diagram illustrating an example technique for operating an assembly including a nanoscale device.

FIG. 13 is an image showing a cross-sectional high-angle annular dark-field (HAADF)-scanning transmission electron microscopy (STEM) image of an example perpendicular magnetic tunnel junction device.

FIG. 14 is an image showing a cross-sectional high-angle annular dark-field (HAADF)-scanning transmission electron microscopy (STEM) image of an example assembly including a perpendicular magnetic tunnel junction (PMTJ) device, first and second conductive layers, and an insulating region.

FIG. 15 is a chart representing a resistance-current (R-I) curve for a sample PMTJ device defining an electron-transparent width.

FIG. 16 is a chart representing a resistance-current (R-I) curve for an original PMTJ device.

FIG. 17A is image showing a bright-field (BF) STEM image of a PMTJ device before a focal series acquisition.

FIG. 17B is image showing a bright-field (BF) STEM image of a PMTJ device after the focal series acquisition.

FIG. 17C is image showing a bright-field (BF) STEM image of a PMTJ device before a super X energy dispersive X-ray (EDX) elemental map acquisition.

FIG. 17D is image showing a bright-field (BF) STEM image of a PMTJ device after the EDX elemental map acquisition.

FIG. 18A is image showing a STEM image of an MgO layer of a sample PMTJ device before applying a current.

FIG. 18B is image showing a STEM image of the MgO layer of the sample PMTJ device after applying a 100 μA current.

FIG. 18C is image showing a STEM image of the MgO layer of the sample PMTJ device after applying a 500 μA current.

FIG. 19A is image showing a HAADF-STEM image of a sample PMTJ device before a forty-fifth duty cycle.

FIG. 19B is image showing a HAADF-STEM image of the sample PMTJ device after the forty-fifth duty cycle.

FIG. 19C is image showing a HAADF-STEM image of the sample PMTJ device after a forty-sixth duty cycle.

FIG. 20A is image showing a HAADF-STEM image of a sample PMTJ device before a duty cycle with a current of Iₘₐₓ=1000 μA.

FIG. 20B is image showing a HAADF-STEM image of the sample PMTJ device after the duty cycle with a current of Iₘₐₓ=1000 μA.

FIG. 21A is image showing a HAADF-STEM image of a sample PMTJ device at room temperature.

FIG. 21B is image showing a HAADF-STEM image of the sample PMTJ device at a temperature of 400°C.

FIG. 21C is image showing a HAADF-STEM image of the sample PMTJ device at a temperature of 450°C.

FIG. 21D is image showing a HAADF-STEM image of the sample PMTJ device at a temperature of 550°C.

### DETAILED DESCRIPTION

The present disclosure may be understood more readily by reference to the following detailed description taken in connection with the accompanying figures and examples, which form a part of this disclosure. It is to be understood that this disclosure is not limited to the specific devices, methods, applications, conditions or parameters described and/or shown herein, and that the terminology used herein is for the purpose of describing particular examples and is not intended to be limiting of the claims. When a range of values is expressed, another example includes from the one particular value and/or to the other particular value. Similarly, when values are expressed as approximations, by use of the antecedent “about,” it will be understood that the particular value forms another example. All ranges are inclusive and combinable. Further, a reference to values stated in a range includes each and every value within that range.

It is to be appreciated that certain features of the disclosure which are, for clarity, described herein in the context of separate examples, may also be provided in combination in a single example. Conversely, various features of the disclosure that are, for brevity, described in the context of a single example, may also be provided separately or in any subcombination.

The present disclosure generally relates to assemblies and techniques for analyzing nanoscale device operation (e.g., when subjected to predetermined applied voltages and electrical currents). While a nanoscale device can be imaged before breakdown or after breakdown, such a comparison may not account for an entire failure path, unless the nanoscale device is imaged during operation, or during a transition from a pre-breakdown to a breakdown state. Thus, imaging during operation may facilitate identification of root causes of device failure and evolution of the changes in constituent materials, interfaces, and contacts in the nanoscale device. For example, imaging the nanoscale device during operation and/or during transition to a breakdown state may identify structural and compositional changes in the materials, interfaces, and contacts in the devices occurring during its operation that would be responsible for the eventual device failure.

In some examples, assemblies and techniques according to the present disclosure may be used to image a nanoscale device (e.g. an MTJ-based device) during operation of the nanoscale device. One or more images generated before, during, and/or after operation may be analyzed to determine changes in structure and composition during different states of the device (e.g., operational states or breakdown states). In some examples, techniques according to the present disclosure may be used to prepare a relatively thin electron-transparent device from a functional nanoscale device, the electron-transparent device being amenable to electron-based imaging (e.g., tunnel electron microscopy) while functionally operating similar to the original nanoscale device under expected operational conditions during imaging. In some examples, assemblies and techniques according to the present disclosure may be used to determine structural and compositional changes of a nanoscale device with time under various operational and/or breakdown conditions and, thereby, determine potential origins or causes of device failure. Thus, assemblies and techniques according to the present disclosure may provide efficient and precise identification of the origins of nanoscale device, and guide device design and development to for promoting device performance, quality, reliability and/or operational life.

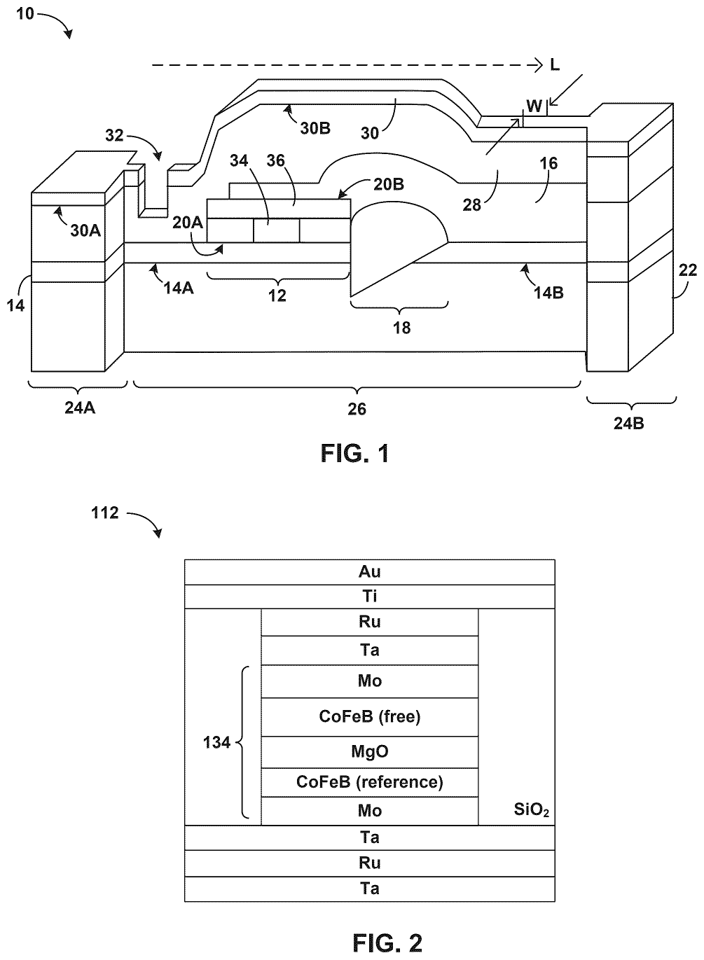

FIG. 1 is a conceptual diagram illustrating a perspective view of an assembly 10 including a nanoscale device 12, a first conductive layer 14, and a second conductive layer 16. Nanoscale device 12 may include any electronic device, for example, a semiconductor device. Assembly 10 may be used to image nanoscale device 12 during operation of nanoscale device 12. One or both of first conductive layer 14 or second conductive layer 16 may be used to apply a voltage and/or pass current through nanoscale device 12 to operate nanoscale device 12. Thus, first conductive layer 14 and second conductive layer are configured to at least partially contact nanoscale device 12.

First conductive layer 14 may include any suitable conductive composition. In some examples, first conductive layer 14 includes at least a first metal species (e.g., a metal or an alloy). For example, first conductive layer 14 includes one or both of Tantalum or Ruthenium. In some examples, first conductive layer 14 includes both of Tantalum and Ruthenium. In some examples, first conductive layer 14 includes a first sublayer including Tantalum, a second sublayer including Ruthenium, and a third sublayer including Tantalum.

Second conductive layer 16 may include any suitable conductive composition, and may be identical to, similar to, or different from the composition of first conductive layer 14. In some examples, second conductive layer 16 includes at least a second metal species. For example, second conductive layer 16 may include Platinum. In some examples, second conductive layer 16 consists essentially of (e.g., excluding minor impurities) or consists of Platinum.

First conductive layer 14 may extend along a longitudinal axis L. First conductive layer 14 may include a first portion 14A and a second portion 14B laterally spaced from first portion 14A by an insulating region 18. First portion 14A of first conductive layer 14 is configured to at least partially contact nanoscale device 12. Second conductive layer 16 may extend along the longitudinal axis L, for example, substantially parallel to first conductive layer 14 in at least a portion of second conductive layer 16. Second conductive layer 16 may extend over second portion 14B of first conductive layer 14 and insulating region 18. For example, second conductive layer 16 may extend over at least a portion of insulating region 18. In some examples, second conductive layer 16 extends over an entirety of insulating region 18, for example, along longitudinal axis L and in a plane parallel to first conductive layer 14. Second conductive layer 16 is configured to at least partially contact nanoscale device 12.

Thus, nanoscale device 12 may at least partially contact first portion 14A of first conductive layer 14 and at least partially contact second conductive layer 16. For example, at least a portion of nanoscale device 12 may be sandwiched between at least a portion of first portion 14A of first conductive layer 14 and at least a portion of second conductive layer 16. In some examples, nanoscale device 12 defines a first face 20A contacting first portion 14A of first conductive layer 14 and a second face 20B opposing first face 20A and contacting second conductive layer 16.

In some examples, insulating region 18 is between nanoscale device 12 and second portion 14B of the conductive layer 14 in a direction along longitudinal axis L. For example, insulating region may laterally abut nanoscale device 12 in the direction along longitudinal axis L. Insulating region 18 may be at least partially occupied by an insulating composition. In some examples, insulating region 18 is completely occupied by the insulating composition. In some examples, the insulating composition includes carbon. In some examples, the insulating composition consists essentially of (e.g., except for minor impurities) or consists of carbon. Insulating region 18 may have any suitable shape or size. In some examples, insulating region 18 defines a wedge between first portion 14A and second portion 14B of first conductive layer 14. For example, the wedge may define a point or narrow tip in a direction facing toward first conductive layer 14 or beyond first conductive layer 14 from second conductive layer 16. Insulating region 18 may define a surface that is coplanar with an interface between first conductive layer 14 and second conductive layer 16, or that extends away from first conductive layer 14 toward second conductive layer 16. Thus, a portion of insulating region 18 at an interface between first conductive layer 14 and second conductive layer 16 may be curved, contoured, bulged, or lenticular, or otherwise projecting away from first conductive layer 14. In some such examples, a portion of second conductive layer 16 adjacent or over insulating region 18 may conform to the shape of insulating region 18, for example, as shown in FIG. 1.

Assembly 10 may further include a substrate supporting one or more of nanoscale device 12, first conductive layer 14, or second conductive layer 16. In some examples, assembly 10 further includes a device substrate 22. Device substrate 22 may include any suitable dielectric material. In some examples, device substrate 22 includes one or both of Silicon or silicon dioxide. In some examples, device substrate 22 includes silicon dioxide and Silicon (e.g., silicon dioxide on Silicon). In some examples, device substrate 22 consists essentially of (e.g., except for minor impurities) or consists of silicon dioxide. In some examples, device substrate 22 consists essentially of (e.g., except for minor impurities) or consists of elemental Silicon.

In examples in which assembly 10 includes device substrate 22, insulating region 18 may extend at least partially within device substrate 22. For example, as shown in FIG. 1, insulating region 18 extends from first conductive layer 14 into a depth of device substrate 22. Extending insulating region 18 into dielectric substrate 22 may reduce or prevent stray currents or stray fields, from example, extending from first portion 14A of first conductive layer 14 to second portion 14B through or across device substrate 22. In some examples, insulating region 18 extends into dielectric substrate 22 to a depth that is at least 10%, at least 50%, at least 100%, or at least 200%, of a thickness of first conductive layer 14.

Assembly 10 may define terminals 24 to apply voltage or current to nanoscale device 10. For example, assembly 10 may define a first terminal 24A and a second terminal 24B (collectively referred to as terminals 24) opposing first terminal 24A in a direction along longitudinal axis L. In some examples, terminals 24 are defined by one or more portions or layers of assembly 10, for example, continuously or integrally formed by regions or portions of one or more layers of assembly 10. For example, first terminal 24A may include at least a portion of device substrate 22 and a portion of first portion 14A of first conductive layer 14. Second terminal 24B may include at least a portion of device substrate 22, a portion of second portion 14B of first conductive layer 14 opposing first terminal 24A, and a portion of second conductive layer 16. In some examples, first portion 14A of first conductive layer 14 extends to first terminal 24A, and second portion 14B of first conductive layer 14 extends to second terminal 24B.

At least a middle portion of assembly 10 may define an electron-transparent width W in a direction transverse to longitudinal axis L. For example, a middle portion 26 between terminals 24 may define electron-transparent width W. Electron-transparent width W may be sufficiently small to allow electron-based imaging of nanoscale device through middle portion 26 (e.g., TEM or STEM imaging). Electron-transparent width W may be less than or equal to 1000 nm, less than or equal to 800 nm, or less than or equal to 100 nm (e.g., depending on the energy of electrons used for imaging). In some examples, electron-transparent width W is less than or equal to 70 nm. For example, electron-transparent width W may be less than or equal to 50 nm.

In some examples, at least one of first terminal 24A or second terminal 24B has a respective width greater than electron-transparent width W. In some such examples, each of first terminal 24A and second terminal 24B has a respective width greater than electron-transparent width W. In some examples, the width of first terminal 24A or second terminal 24B may be greater than electron-transparent width W, but remaining electron-transparent (for example, a second electron-transparent width). In some examples, the width of first terminal 24A or second terminal 24B may be greater than electron-transparent width W and not electron-transparent (e.g., a width that does not permit sufficient electron transfer for electron-based imaging).

Middle portion 26 may be defined by one or more layers of assembly 10, for example, continuously or integrally formed by regions or portions of one or more layers of assembly 10. For example, middle portion 26 may include one or more of at least a portion of nanoscale device 12, a portion of first portion 14A of first conductive layer 14, a portion of second portion 14B of first conductive layer 14, at least a portion of second conductive layer 16, at least a portion of insulating region 18, or at least a portion of device substrate 22. In some examples, middle portion 26 includes an entirety of nanoscale device 12. In some examples, middle portion 26 includes an entirety of insulating region 18. Middle portion 26 may continuously or integrally extend within terminals 24. For example, one or more layers of middle portion 26 may continuously or integrally extend within terminals 24.

Assembly 10 may include further layers. For example, assembly 10 may further include a protective layer 28 extending over first portion 14A of first conductive layer 14 and over second conductive layer 16. Protective layer 28 may protect one or more layers or components of assembly 10 from one or more of oxidation, corrosion, stray fields, or stray currents, or may insulate one or more layers or components of assembly 10 from other layers. In some examples, protective layer 28 contacts at least a portion of nanoscale device 12. In some examples, protective layer 28 contacts or covers at least a portion of second face 20B of nanoscale device 12. The composition of protective layer 28 may be identical to or similar to that described with reference to the insulating composition in insulation region 18. In some examples, protective layer 28 includes carbon. In some examples, protective layer 28 consists essentially of (e.g., except for minor impurities) or consists of carbon.

Assembly 10 may further include a third conductive layer 30 that at least partially extends over protective layer 28. In some examples, protective layer 28 is between nanoscale device 12 and third conductive layer 30. In some examples, third conductive layer 30 is substantially coextensive with or coextensive with protective layer 28. Third conductive layer 28 may include a composition similar to or identical to that described with reference to second conductive layer 16. In some examples, third conductive layer 30 includes Platinum. In some examples, third conductive layer 30 consists essentially of (e.g., except for minor impurities) or consists of Platinum.

In some examples, third conductive layer 30 defines an insulating gap 32 (e.g., a notch) separating third conductive layer 30 into a first portion 30A and a second portion 30B. In some examples, insulating gap 32 may be between first terminal 24A and nanoscale device 12 or terminal 24B in a direction along longitudinal axis L. Insulating gap 32 may be occupied with an insulating composition identical to or similar to that described with reference to insulating region 18. Second portion 30B of third conductive layer 30 may extend over nanoscale device 12 (e.g., with or without intervening layers in between). In some examples, second conducting layer 16 is between second portion 30B of third conductive layer 30 and nanoscale device 12. First portion 30A of third conductive layer 30A may extend to first terminal 24A, and where second portion 30B of third conductive layer 30B may extend to the second terminal 24B. Middle portion 26 of assembly 10 between first terminal 24A and second terminal 24B may include at least a portion of one or both of protective layer 28 or third conductive layer 30.

In some examples, nanoscale device 12 includes a magnetic tunnel junction (MTJ) 34. MTJ 34 may be a perpendicular MTJ, or any other type of MTJ. In some examples, MTJ 34 includes a Molybdenum-capped CoFeB|MgO|CoFeB core, as described with reference to FIGS. 2A and 2B. In some examples, nanoscale device 12 includes a conductive pad 36. Conductive pad 36 may define second face 20B of nanoscale device 12. Conductive pad 36 may include any suitable conductive composition. In some examples, conductive pad 36 includes one or more of Aurum (gold), Ruthenium, Titanium, or Tantalum. In some examples, MTJ 34 is a nanopillar MTJ in conductive contact with conductive pad 36.

FIG. 2 is a conceptual diagram illustrating a side view of an example nanoscale device 112 including a magnetic tunnel junction (MTJ) 134. Nanoscale device 12 described with reference to FIG. 1 may include nanoscale device 112, or any other nanoscale device. In some examples, nanoscale device 112 is a nanopillar PMTJ device. MTJ 134 includes layers of Mo (1.2 nm), Co₂₀Fe₆₀B₂₀ (1 nm), MgO (0.9 nm) Co₂₀Fe₆₀B₂₀ (1.2 to 1.7 nm), Mo (1.9 nm) (thicknesses of layers in parentheticals) and is located between a first electrode including Tantalum, Ruthenium, and Tantalum layers, and a second electrode including Tantalum, Ruthenium, Titanium, and Aurum layers. The two CoFeB layers in MTJ 134 are FM layers with PMA, with a first (bottom) CoFeB layer between MgO and Molybdenum layers being a reference layer, and a second (top) CoFeB layer being a free layer. The MgO layer in MTJ 134 serves as an insulating layer, and the Molybdenum layers in MTJ 134 act as buffer and capping layers. Various layers of nanoscale device 112 may be supported by an SiO₂ matrix.

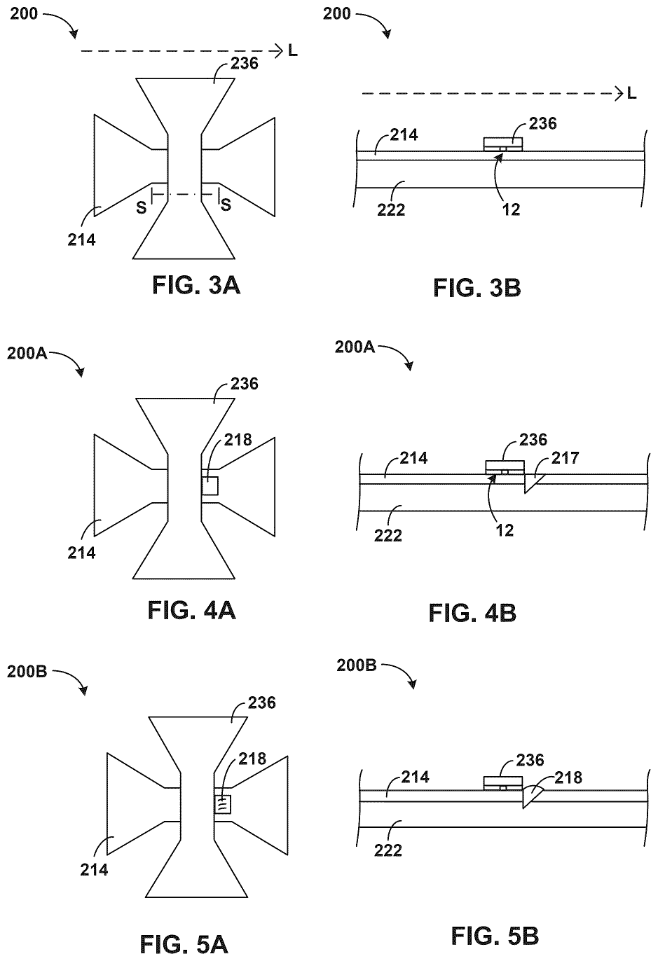

An example technique for forming assembly 10 is described with reference to FIGS. 3A to 10B representing different stages of formation.

FIG. 3A is a conceptual diagram illustrating a top view of an assembly 200 in a first stage of formation including nanoscale device 12 on a first conductive layer 214. FIG. 3B is a conceptual diagram illustrating a side view of the assembly of FIG. 3A along line S-S. Assembly 200 includes a pad layer 236, and nanoscale device is between first conductive layer 214 and pad layer 236. First conductive layer 214 may be supported by a device layer 222, similar to device layer 22 described with reference to FIG. 1. The composition of first conductive layer 214 may be identical to or similar to that described with reference to first conductive layer 14 of FIG. 1. The composition of pad layer 236 may be identical to or similar to that described with reference to conductive pad 36 of FIG. 1. MTJ 34 of nanoscale device 12 may be positioned between pad layer 236 and first conductive layer 214. First conductive layer and pad layer 236 may form a cross as shown in FIG. 3A.

FIG. 4A is a conceptual diagram illustrating a top view of the assembly of FIG. 3A in a second stage of formation 200A further including an insulating gap 217. FIG. 4B is a conceptual diagram illustrating a side view of assembly 200A of FIG. 4A. Insulating gap 217 is defined in first conductive layer 214, for example, by machining or cutting a portion of first conductive layer 214 and/or a portion of device layer 222. Insulating gap 217 may be defined to laterally abut nanoscale device 12, for example, in a direction along longitudinal axis L.

FIG. 5A is a conceptual diagram illustrating a top view of the assembly of FIG. 4A in a third stage of formation 200B further including an insulating composition in insulating gap 217 to form an insulating region 218. FIG. 5B is a conceptual diagram illustrating a side view of assembly 200B of FIG. 5A. The insulating composition may be deposited by any suitable technique, for example, vapor deposition or sputtering. The insulating composition may be deposited such that at least a portion of the insulating composition abuts nanoscale device 12.

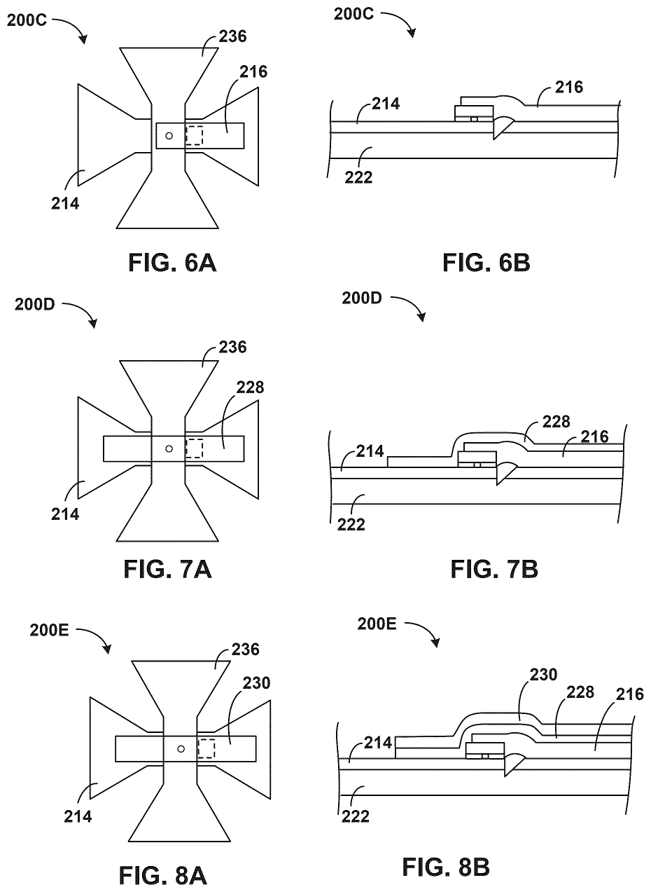

FIG. 6A is a conceptual diagram illustrating a top view of the assembly of FIG. 5A in a fourth stage of formation 200C further including a second conductive layer 216. FIG. 6B is a conceptual diagram illustrating a side view of assembly 200C of FIG. 6A. Second conductive layer 216 may have a composition similar to or identical to that described with reference to second conductive layer 16 of FIG. 1. Second conductive layer 216 may be deposited by any suitable technique, for example, vapor deposition or sputtering.

FIG. 7A is a conceptual diagram illustrating a top view of the assembly of FIG. 6A in a fifth stage of formation 200D further including a protective layer 228. FIG. 7B is a conceptual diagram illustrating a side view of assembly 200D of FIG. 7A. Protective layer 228 may have a composition similar to or identical to that described with reference to protective layer 28 of FIG. 1. Protective layer 228 may be deposited by any suitable technique, for example, vapor deposition or sputtering.

FIG. 8A is a conceptual diagram illustrating a top view of the assembly of FIG. 7A in a sixth stage of formation 200E further including a third conductive layer 230. FIG. 8B is a conceptual diagram illustrating a side view of the assembly of FIG. 8A. Third conductive layer 230 may have a composition similar to or identical to that described with reference to third conductive layer 30 of FIG. 1. Third conductive layer 230 may be deposited by any suitable technique, for example, vapor deposition or sputtering.

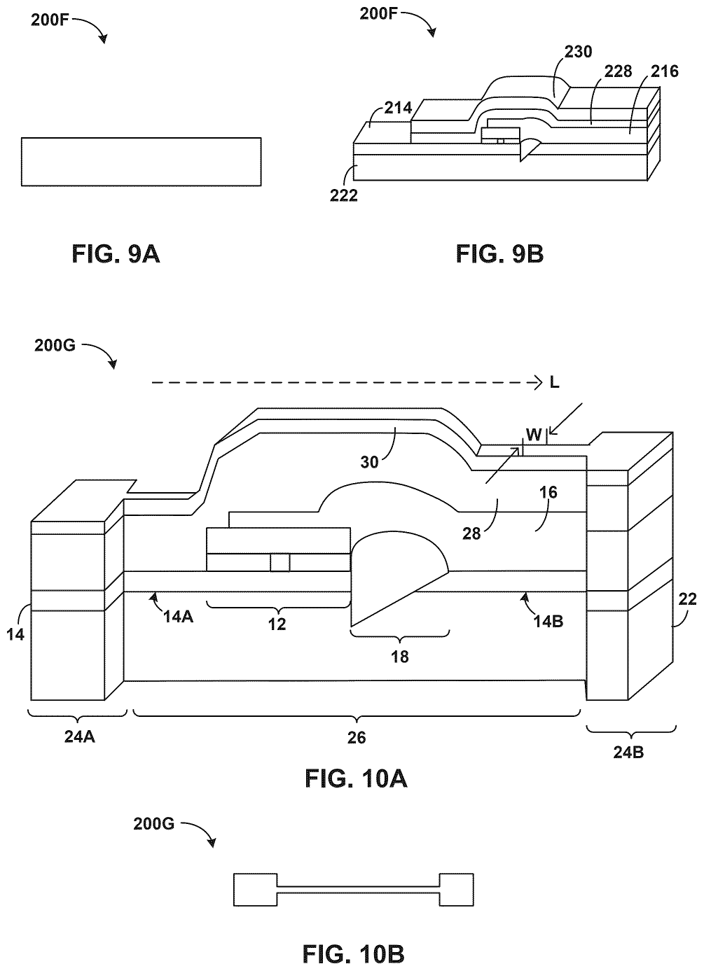

FIG. 9A is a conceptual diagram illustrating a top view of the assembly of FIG. 8A trimmed in a seventh stage of formation 200F. FIG. 9B is a conceptual diagram illustrating a perspective view of assembly 200F of FIG. 9A. In the trimmed formation, the width of assembly 200F is similar to the width of first terminal 24A and second terminal 24B of FIG. 1, and the length of assembly 200F is similar to a length of assembly 10 of FIG. 1 along longitudinal axis L.

FIG. 10A is a conceptual diagram illustrating a perspective view of the assembly of FIG. 9A in an eight stage of formation 200G further cut to define electron-transparent width W. FIG. 10B is a conceptual diagram illustrating a top view of assembly 200G of FIG. 10A. In particular, a middle section of assembly 200F of FIG. 9A is cut to form middle section 26 of assembly 200G. Assembly 200G is substantially similar to assembly 10, with layers 214, 216, 222, 228, and 230 of assembly 200F respectively forming layers 14, 16, 22, 28, and 30 of assembly 200G. Further, layers 30 and/or 28 of assembly 200G can be cut to form insulating gap 32 shown in FIG. 1. Thus, after cutting insulating gap 32, assembly 200G forms assembly 10 of FIG. 1.

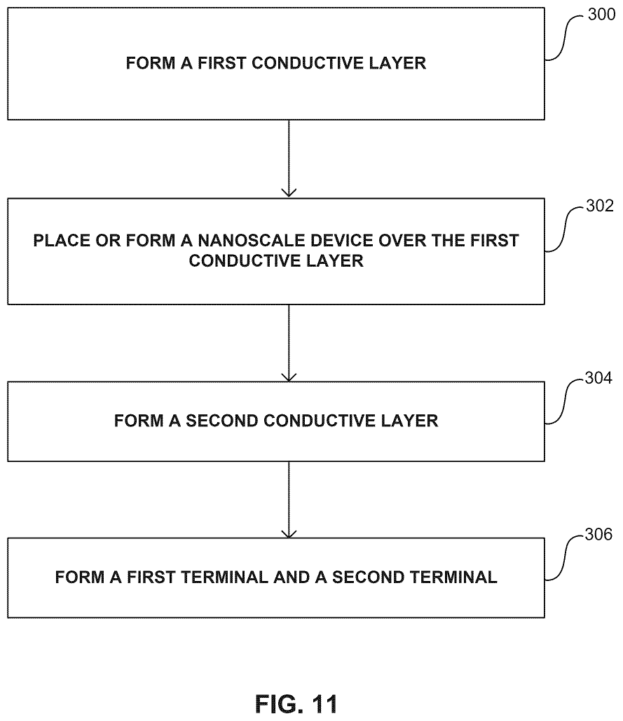

FIG. 11 is a conceptual block diagram illustrating an example technique for forming an assembly including a nanoscale device. While the technique of FIG. 11 is described with reference to assembly 10 of FIG. 1, the technique of FIG. 11 may be used to form any assembly according to the present disclosure, and any other suitable technique may be used to form any assembly according to the present disclosure.

In some examples, the technique includes forming first conductive layer 14 extending along longitudinal axis L (300). First conductive layer 14 may include first portion 14A and second portion 14B laterally spaced from first portion 14A by insulating region 18. In some examples, the forming first conductive layer (300) includes forming a first sublayer including Tantalum; forming a second sublayer including Ruthenium; and forming a third sublayer including Tantalum.

In some examples, the forming first conductive layer (300) includes forming insulating region 18. In some such examples, the technique further includes depositing an insulating composition including carbon in insulating region 18. The technique may further include forming the insulating region defining a wedge between first portion 14A and second portion 14B of first conductive layer 14.

In some examples, the forming first conductive layer (300) further includes depositing first conductive layer 14 over device substrate 22. In some such examples, the technique further includes defining insulating region 18 extending at least partially from first conductive layer 14 to within device substrate 22 (e.g., by cutting one or both of first conductive layer 14 or device substrate 22).

First conductive layer 14 at least partially contacts nanoscale device 12. In some examples, the technique further includes placing or forming nanoscale device 12 over first conductive layer 14 (302). For example, nanoscale device 12 may be positioned or placed in contact with first conductive layer 14. In some examples, nanoscale device 12 is pre-fabricated, and positioned or placed over first conductive layer 14 (302). In other examples, the technique further includes forming nanoscale device 12 over first conductive layer 14 (302). For example, nanoscale device 12 may be formed at least partially contacting first portion 14A of first conductive layer 14. The technique may further include forming second conductive layer 16 extending along the longitudinal axis (304). Second conductive layer 16 may extend over second portion 14B and insulating region 18. Second conductive layer 16 may at least partially contact nanoscale device 12. At least a portion of assembly 10 may define electron-transparent width W in a direction transverse to longitudinal axis L.

The technique may further include forming first terminal 24A and second terminal 24A opposing first terminal 24A in a direction along longitudinal axis L (306). Forming first terminal 24A and second terminal 24B may include cutting a middle portion of assembly 10 to form middle section 26 defining electron-transparent width W, where first terminal 24A and the second terminal 24B each have a respective width greater than electron-transparent width W. For example, the technique may further include forming the electron-transparent width by focused ion beam (FIB) cutting at least respective portions of first conductive layer 14, second conductive layer 16, and/or nanoscale device 12.

The technique may further include forming protective layer 228 extending over first portion 14A of first conductive layer 14 and over second conductive layer 16. In some examples, the technique further includes forming third conductive layer 230 at least partially extending over protective layer 228, where protective layer 228 is between nanoscale device 12 and third conductive layer 230.

In some examples, nanoscale device 12 includes magnetic tunnel junction (MTJ) 34. In some such examples, the technique further includes forming MTJ 34 over first conductive layer 14. In other such examples, the technique further includes forming MTJ 34 over a temporary substrate; and moving MTJ 34 from the temporary substrate to first conductive layer 14.

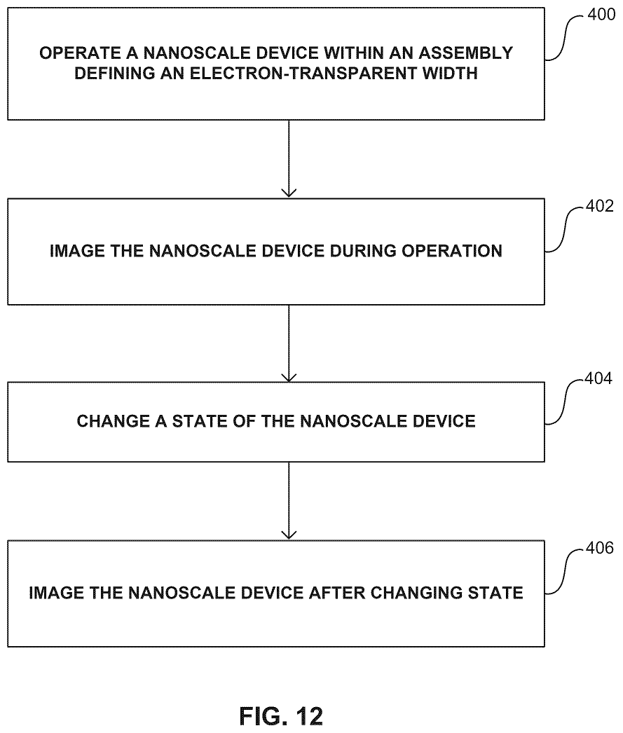

FIG. 12 is a conceptual block diagram illustrating an example technique for operating assembly 10 including nanoscale device 12. While the technique of FIG. 12 is described with reference to assembly 10 of FIG. 1, the technique of FIG. 12 may be used to analyze any assembly according to the present disclosure, and any other suitable technique may be used to analyze any assembly according to the present disclosure.

In some examples, the example technique includes operating nanoscale device 12 within assembly 10 (400). The technique may further include imaging nanoscale device 12 within assembly 10 during the operating to generate an image of the nanoscale device (402).

The imaging (402) may include scanning transmission electron microscopy. In some examples, the image is a first image, and the technique may further include, after the imaging (402) to generate the first image, changing a state of nanoscale device 12 from a first state to a second state (404). For example, the changing the state (404) may include applying a voltage, a current, or a temperature to nanoscale device 12 (or assembly 10), or changing any suitable operational parameter of nanoscale device 12 or assembly 10. The method may further include, after changing the state of nanoscale device 12, imaging nanoscale device 12 within assembly 10 to generate a second image of nanoscale device 12 (406).

The technique may further include comparing the first image and the second image to determine at least one difference in nanoscale device 12 between the first state and the second state. In some examples, the first state is an operational state, and where the second state is a breakdown state.

Thus, assemblies and techniques according to the present disclosure may be used to assess the effect of changes in operational parameters or conditions, or of environmental conditions, on nanoscale devices. For example, assemblies and techniques according to the present disclosure may be used to determine device configurations associated with transitions between different device states, conditions that may promote efficiency or reduce or prevent breakdown of nanoscale devices, conditions that may result in a reduction or loss of efficiency, or conditions that may result in a breakdown of nanoscale devices.

### EXAMPLES

### Example 1

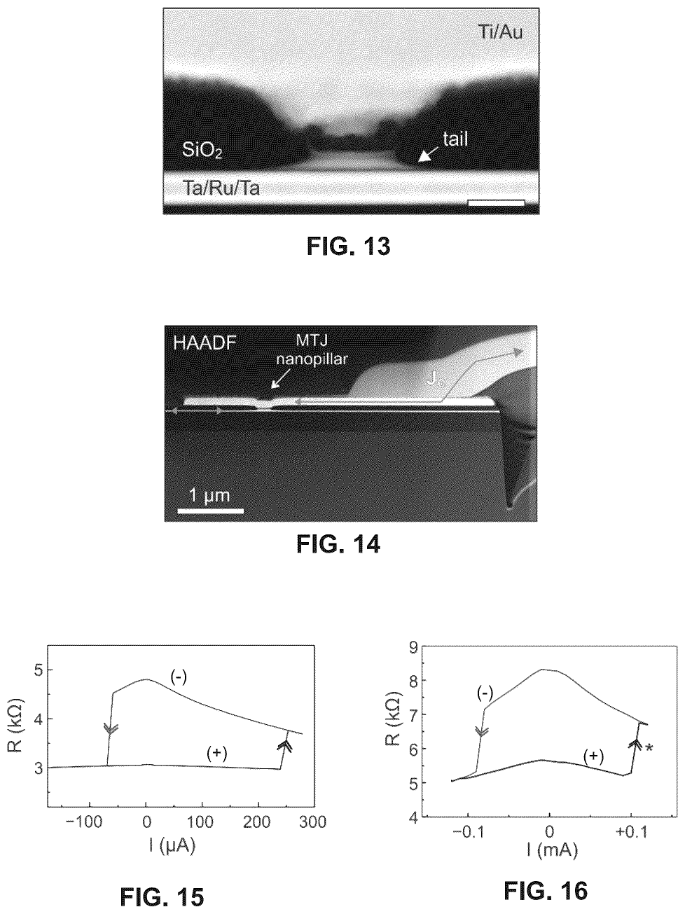

Sample PMTJ devices were fabricated having a structure similar to that of device 112 described with reference to FIG. 2A. Structural quality of the PMTJ devices was evaluated by STEM analysis of more than 20 nanopillar PMTJ devices with a diameter of ˜50 nm. A cross-sectional high-angle annular dark-field (HAADF)-STEM image of one of the PMTJ devices is shown in FIG. 13. The nanopillars had a conical frustum shape at the base, with a diameter at the bottom Ta electrode of about ˜100 nm. Additionally, a tail was observed at the bottom of the PMTJ core unit, which is result of the standard ion milling process.

Next, the atomic structures at the core MTJ units were analyzed through STEM imaging and energy dispersive X-ray (EDX) elemental maps confirming the composition of each layer. A bright-field (BF)-STEM mode was utilized to visualize the lattice contrast with a modest contrast difference between layers. The MgO layer had a small grain (5 to 10 nm) polycrystalline atomic structure, rough interfaces, and a non-uniform layer thickness (d=9±2 Å).

### Example 2

To investigate any structural modifications occurring during the operation of PMTJ devices and the subsequent breakdown behavior, in-situ STEM PMTJ devices were prepared to allow current flow in the vertical direction, mirroring the natural operation of devices. A HAADF-STEM image of such a device is shown in FIG. 14. An R-I curve was determined for the prepared in-situ device before inserting it into TEM, and shown in FIG. 15. An R-I curve for the original is shown in FIG. 16. In both FIGS. 15 and 16, the line marked (+) is the curve for a positive biasing direction, and the line marked (−) is the curve for a negative biasing direction. In FIG. 16, the asterisk (*) marks the parallel to antiparallel tunneling magnetoresistance (TMR) switching during positive biasing. As seen in FIGS. 15 and 16, the R-I curve for the in-situ device exhibits TMR switching similar to the original device. For example, both R-I curves of FIGS. 15 and 16 have a house-like shape, which is characteristic of the bias dependency in TMR. This observation confirmed that the resistance change observed in the in-situ STEM device is TMR switching rather than memristor-type resistive switching.

### Example 3

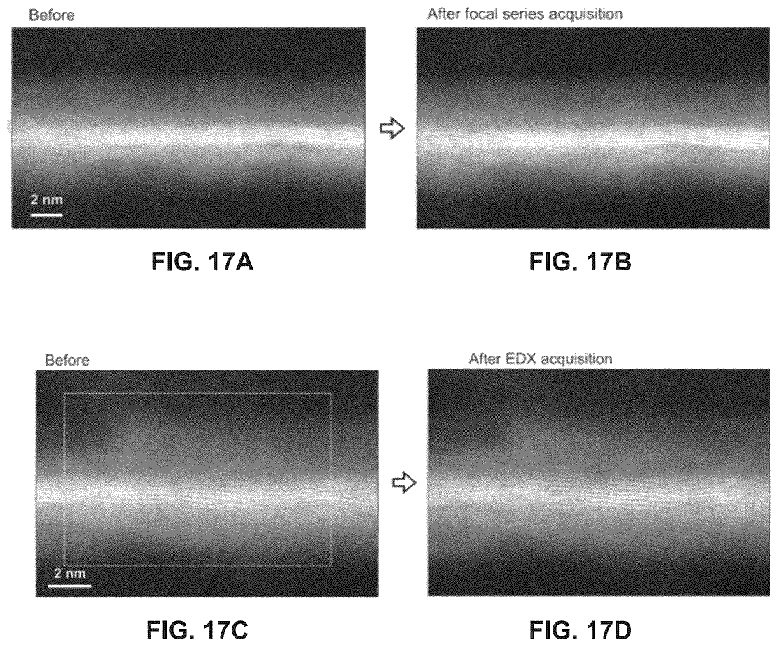

For observation of PMTJ devices breakdown, additional PMTJ devices with a larger diameter of 200 nm were made to enhance the success rate of in-situ STEM sample preparation. In-situ STEM experiments were conducted by running the electric bias duty-cycles, using current as an input over time. To evaluate the effects of current on device performance and structure, the maximum current (Iₘₐₓ) of a duty-cycle was gradually increased and the resistance was measured. The initial resistance of in-situ devices, obtained from the first duty-cycle, exhibited an inversely proportional relationship with respect to STEM sample thickness, or cross-sectional area, indicating current flow through the PMTJ nanopillars. When a relatively small electric current (Iₘₐₓ≤500 μA) duty-cycles were applied to in-situ STEM device, a gradual reduction of resistance as a function of current was observed. Such resistance change is an indication of soft breakdown. A series of STEM images of the PMTJ core were acquired after each duty-cycle to study the structural change responsible for this soft breakdown. For direct comparison, after each duty-cycle, a focal series of BF-STEM images were collected and STEM image with the same focal depth was selected and compared with the corresponding image obtained after previous duty-cycle. It was observed that the sample damage from the electron beam irradiation was minimal in these STEM measurements, as demonstrated in FIGS. 17A to 17D.

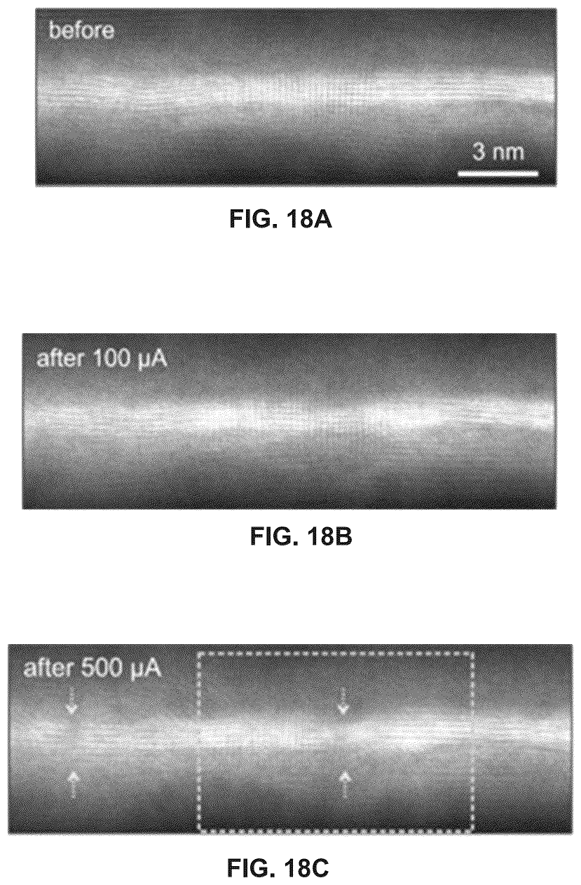

The results reveal that the thickness of the MgO layer becomes even more non-uniform with roughness of the interfaces with the CoFeB layers, growing from Δd=2 Å to Δd 32 5 Å upon biasing, which is comparable to its original thickness. The results of STEM-EDX analysis show that Mg atoms migrate, resulting in the formation of ultra-thin MgO regions consistent with BF-STEM images as shown in FIGS. 18A to 18C. The ultra-thin MgO region creates a path for current leakage, which is a source for a soft breakdown. The nanopillar edge regions also showed structural degradation due to electric biasing. The tail of the top Ta layer on the PMTJ unit underwent reshaping and formed connection with the bottom Ta layer. This occurred at very low currents, even at 0.01 μA, suggesting a high structural vulnerability of the edge regions. This conducting edge path is the second source for leakage current contributing to the observed overall decrease of PMTJ nanopillar resistance.

### Example 4

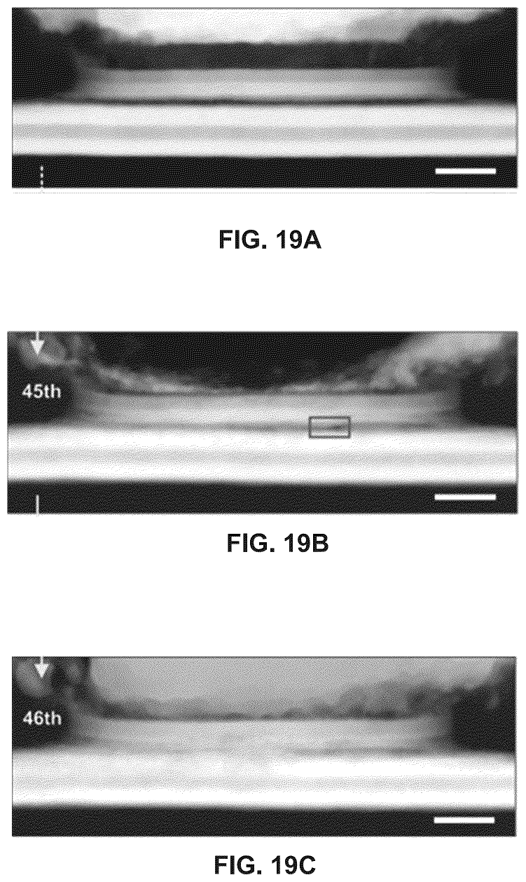

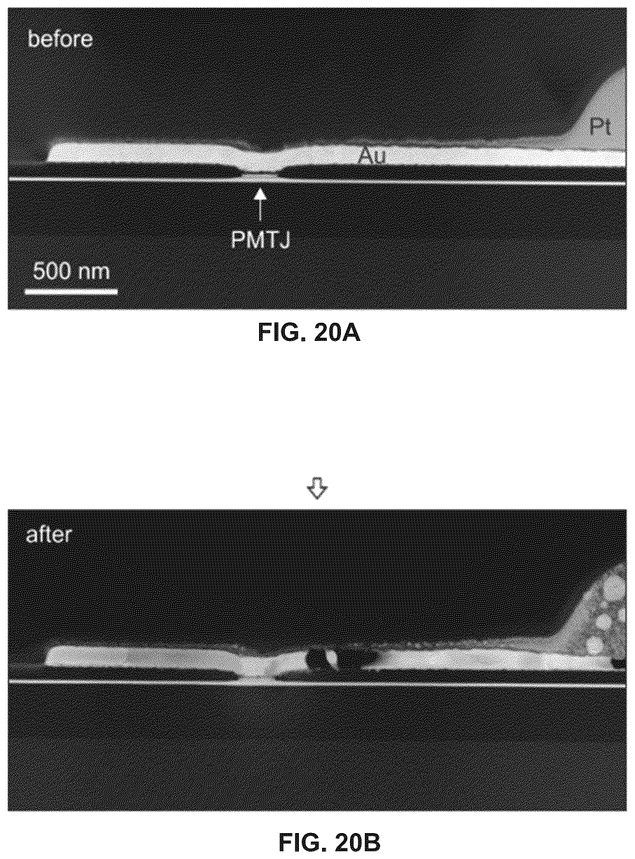

When duty-cycle with a current, Iₘₐₓ≈700 μA, was repeatedly applied to in-situ STEM PMTJ device, the device melted down after 45 cycles, as shown in FIGS. 19A to 19C. Upon biasing, when the current is passing through a PMTJ device, it produces joule heating, which then melts the electrodes and drives long-range (μm-scale) electromigration. Before the meltdown of PMTJ device, even at duty-cycles less then 30, the long-range migration of atoms was visible. Considerable changes in Au/Ti contact were observed. Mobile Au diffuses into Ti region and makes direct contact with the top Ru electrode. At this stage no drastic change in the R-I curve, i.e. TMR behavior, is observed. With repetition of duty-cycles, the heat accumulates then the top Au electrode melts away and resistance was observed to increase. At this stage, the collapse of the PMTJ core unit and the meltdown of Ta and Ru layers took place, resulting in complete breakdown of the device. EDX elemental maps acquired right-after the meltdown of the PMTJ core show that the top and bottom CoFeB layers merge into one, and Mg atoms diffuse out (FIGS. 19A to 19C). Such a complete breakdown was observed after applying a few duty-cycles with a current Iₘₐₓ≈1000 μA (FIGS. 20A and 20B). The number of duty-cycles that it takes to achieve this breakdown was inversely proportional to the magnitude of applied current.

### Example 5

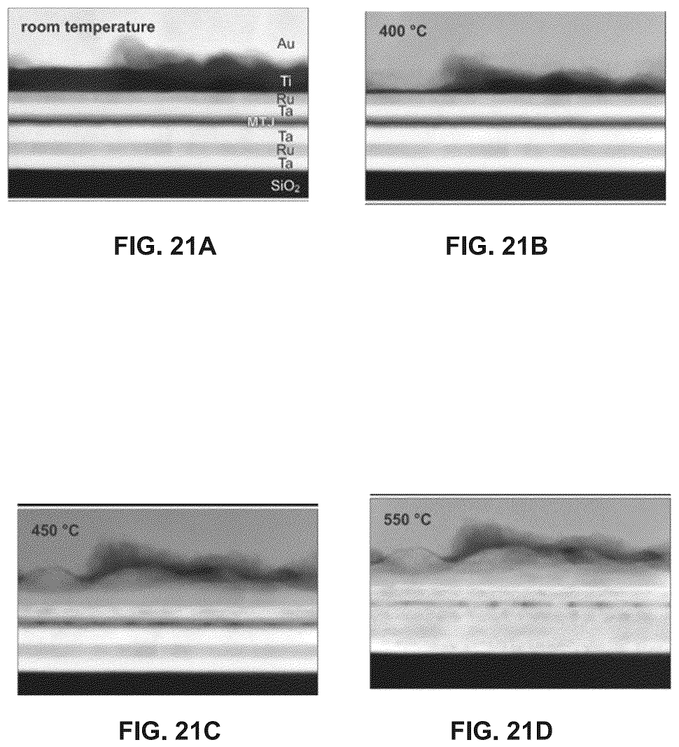

To evaluate the effects of pure heating (without electromigration) on PMTJ devices, additional in-situ STEM heating experiments were conducted (FIGS. 21A to 21D). In these experiments, the top Au contact melted first at ˜250° C., followed by Ru at ˜450° C. (FIG. 21C), and eventually Ta at ˜550° C. (FIG. 21D). When biasing was applied to these samples, after completion of heating experiments, electromigration was observed again and, in some case, it showed long mm-scale migration of atoms. These observations confirmed that upon biasing the core and electrode layers of PMTJ device experience both considerable electromigration and joule heating. They also indicate that during operation of the device, in presence of electromigration, the meltdown should occur at even lower temperatures than those observed in pure heating measurements.

The following enumerated clauses describe aspects in accordance with the present disclosure.
Clause 1: An assembly including: a first conductive layer extending along a longitudinal axis, the first conductive layer including a first portion and a second portion laterally spaced from the first portion by an insulating region, the first portion of the first conductive layer being configured to at least partially contact a nanoscale device; and a second conductive layer extending along the longitudinal axis, the second conductive layer extending over the second portion and the insulating region, the second conductive layer being configured to at least partially contact the nanoscale device, where at least a portion of the assembly defines an electron-transparent width in a direction transverse to the longitudinal axis.
Clause 2: The assembly of clause 1, where the insulating region is between the nanoscale device and the second portion of the first conductive layer in a direction along the longitudinal axis.
Clause 3: The assembly of any of clauses 1 or 2, where the nanoscale device defines a first face contacting the first portion of the first conductive layer and a second face opposing the first face and contacting the second conductive layer.
Clause 4: The assembly of any of clauses 1 to 3, where the assembly defines a first terminal and a second terminal opposing the first terminal in a direction along the longitudinal axis, and where the first terminal and the second terminal each have a respective width greater than the electron-transparent width.
Clause 5: The assembly of clause 4, where the first portion of the first conductive layer extends to the first terminal, and where the second portion of the first conductive layer extends to the second terminal.
Clause 6: The assembly of any of clauses 1 to 5, where the first conductive layer includes a first composition including at least a first metal species, and where the second layer includes a second composition including at least a second metal species.
Clause 7: The assembly of clause 6, where the first conductive layer includes Tantalum and Ruthenium.
Clause 8: The assembly of clause 7, where the first conductive layer includes a first sublayer including Tantalum, a second sublayer including Ruthenium, and a third sublayer including Tantalum.
Clause 9: The assembly of any of clauses 6 to 8, where the second conductive layer includes Platinum.
Clause 10: The assembly of clause 9, where the second conductive layer consists of Platinum.
Clause 11: The assembly of any of clauses 1 to 10, where the insulating region is occupied by an insulating composition including carbon.
Clause 12: The assembly of any of clauses 1 to 11, where the insulating region defines a wedge between the first portion and the second portion of the first conductive layer.
Clause 13: The assembly of any of clauses 1 to 12, further including a device substrate.
Clause 14: The assembly of clause 13, where the device substrate includes silicon dioxide.
Clause 15: The assembly of clauses 13 or 14, where the insulating region extends at least partially within the device substrate.
Clause 16: The assembly of any of clauses 1 to 15, further including a protective layer extending over the first portion of the first conductive layer and over the second conductive layer.
Clause 17: The assembly of clause 16, where the protective layer contacts at least a portion of the nanoscale device.
Clause 18: The assembly of any of clauses 16 or 17, where the protective layer includes carbon.
Clause 19: The assembly of any of clauses 16 to 18, further including a third conductive layer at least partially extending over the protective layer, where the protective layer is between the nanoscale device and the third conductive layer.
Clause 20: The assembly of clause 19, where the third conductive layer is coextensive with the protective layer.
Clause 21: The assembly of any of clauses 19 or 20, where the third conductive layer includes Platinum.
Clause 22: The assembly of clause 21, where the third conductive layer consists of Platinum.
Clause 23: The assembly of any of clauses 19 to 22, where the third conductive layer defines an insulating gap separating the third conductive layer into a first portion and a second portion.
Clause 24: The assembly of clause 23, where the second portion of the third conductive layer extends over the nanoscale device, and where the second conducting layer is between the second portion of the third conductive layer and the nanoscale device.
Clause 25: The assembly of any of clauses 23 or 24, where the first portion of the third conductive layer extends to the first terminal, and where the second portion of the third conductive layer extends to the second terminal.
Clause 26: The assembly of any of clauses 1 to 25, where the electron-transparent width is less than or equal to 100 nm.
Clause 27: The assembly of clause 26, where the electron-transparent width is less than or equal to 70 nm.
Clause 28: The assembly of any of clauses 1 to 27, further comprising the nanoscale device, where the nanoscale device includes a magnetic tunnel junction (MTJ).
Clause 29: The assembly of clause 28, where the MTJ is a perpendicular MTJ.
Clause 30: The assembly of clause 29, where the MTJ includes a Molybdenum-capped CoFeB|MgO|CoFeB core.
Clause 31: A method including: forming a first conductive layer extending along a longitudinal axis, the first conductive layer including a first portion and a second portion laterally spaced from the first portion by an insulating region, the first portion of the first conductive layer at least partially contacting a nanoscale device; and forming a second conductive layer extending along the longitudinal axis, the second conductive layer extending over the second portion and the insulating region, the second conductive layer at least partially contacting the nanoscale device; where at least a portion of the assembly defines an electron-transparent width in a direction transverse to the longitudinal axis.
Clause 32: The method of clause 31, where the insulating region is between the nanoscale device and the second portion of the first conductive layer in a direction along the longitudinal axis.
Clause 33: The method of any of clauses 31 or 32, where the nanoscale device defines a first face contacting the first portion of the first conductive layer and a second face opposing the first face and contacting the second conductive layer.
Clause 34: The method of any of clauses 31 to 33, further including forming a first terminal and a second terminal opposing the first terminal in a direction along the longitudinal axis, where the first terminal and the second terminal each have a respective width greater than the electron-transparent width.
Clause 35: The method of clause 34, where the first portion of the first conductive layer extends to the first terminal, and where the second portion of the first conductive layer extends to the second terminal.
Clause 36: The method of any of clauses 31 to 35, where the first conductive layer includes a first composition including at least a first metal species, and where the second layer includes a second composition including at least a second metal species.
Clause 37: The method of clause 36, where the first conductive layer includes Tantalum and Ruthenium.
Clause 38: The method of clause 37, where the forming first conductive layer includes: forming a first sublayer including Tantalum; forming a second sublayer including Ruthenium; and forming a third sublayer including Tantalum.
Clause 39: The method of any of clauses 36 to 38, where the second conductive layer includes Platinum.
Clause 40: The method of clause 39, where the second conductive layer consists of Platinum.
Clause 41: The method of any of clauses 31 to 40, further including depositing an insulating composition including carbon in the insulating region.
Clause 42: The method of any of clauses 31 to 41, further including forming the insulating region defining a wedge between first portion 14A and second portion 14B of first conductive layer 14.
Clause 43: The method of any of clauses 31 to 42, further including depositing the first conductive layer over a device substrate.
Clause 44: The method of clause 43, where the device substrate includes silicon dioxide.
Clause 45: The method of clauses 43 or 44, further including defining the insulating region extending at least partially from the first conductive layer to within the device substrate.
Clause 46: The method of any of clauses 31 to 45, further including forming a protective layer extending over the first portion of the first conductive layer and over the second conductive layer.
Clause 47: The method of clause 46, where the protective layer contacts at least a portion of the nanoscale device.
Clause 48: The method of any of clauses 46 or 47, where the protective layer includes carbon.
Clause 49: The method of any of clauses 46 to 48, further including forming a third conductive layer at least partially extending over the protective layer, where the protective layer is between the nanoscale device and the third conductive layer.
Clause 50: The method of clause 49, where the third conductive layer is coextensive with the protective layer.
Clause 51: The method of any of clauses 49 or 50, where the third conductive layer includes Platinum.
Clause 52: The method of clause 51, where the third conductive layer consists of Platinum.
Clause 53: The method of any of clauses 49 to 52, where the third conductive layer defines an insulating gap separating the third conductive layer into a first portion and a second portion.
Clause 54: The method of clause 53, where the second portion of the third conductive layer extends over the nanoscale device, and where the second conducting layer is between the second portion of the third conductive layer and the nanoscale device.
Clause 55: The method of any of clauses 53 or 54, where the first portion of the third conductive layer extends to the first terminal, and where the second portion of the third conductive layer extends to the second terminal.
Clause 56: The method of any of clauses 31 to 55, further including forming the electron-transparent width by focused ion beam (FIB) cutting at least respective portions of the first conductive layer, the second conductive layer, and the nanoscale device.
Clause 57: The method of any of clauses 31 to 56, where the electron-transparent width is less than or equal to 100 nm.
Clause 58: The method of clause 57, where the electron-transparent width is less than or equal to 70 nm.
Clause 59: The method of any of clauses 31 to 58, where the nanoscale device includes a magnetic tunnel junction (MTJ).
Clause 60: The method of clause 59, further including forming the MTJ over the first conductive layer.
Clause 61: The method of clause 59, further including: forming the MTJ over a temporary substrate; and moving the MTJ from the temporary substrate to the first conductive layer.
Clause 62: The method of any of clauses 60 or 61, where the MTJ is a perpendicular MTJ.
Clause 63: The method of clause 62, where the MTJ includes a Molybdenum-capped CoFeB|MgO|CoFeB core.
Clause 64: A method including: operating a nanoscale device according to the assembly of any of clauses 1 to 30; and imaging the nanoscale device within the assembly during the operating to generate an image of the nanoscale device.
Clause 65: The method of clause 64, where the imaging includes scanning transmission electron microscopy.
Clause 66: The method of any of clauses 64 or 65, where the image is a first image, where the method further includes: after the imaging to generate the first image, changing a state of the nanoscale device from a first state to a second state; and after changing the state of the nanoscale device, imaging the nanoscale device within the assembly to generate a second image of the nanoscale device.
Clause 67: The method of clause 66, further including comparing the first image and the second image to determine at least one difference in the nanoscale device between the first state and the second state.
Clause 68: The method of clause 67, where the first state is an operational state, and where the second state is a breakdown state.

Various examples have been described. Those skilled in the art will appreciate that numerous changes and modifications can be made to the examples described in this disclosure and that such changes and modifications can be made without departing from the spirit of the disclosure. These and other examples are within the scope of the following claims.

What is claimed is:

1. An assembly comprising:
a first conductive layer extending along a longitudinal axis, the first conductive layer comprising a first portion and a second portion laterally spaced from the first portion by an insulating region, the first portion of the first conductive layer being configured to at least partially contact a nanoscale device; and
a second conductive layer extending along the longitudinal axis, the second conductive layer extending over the second portion and the insulating region, the second conductive layer being configured to at least partially contact the nanoscale device,
wherein at least a portion of the assembly defines an electron-transparent width in a direction transverse to the longitudinal axis.

2. The assembly of claim 1, wherein the insulating region is configured to positioned between the nanoscale device and the second portion of the first conductive layer in a direction along the longitudinal axis.

3. The assembly of claim 1, wherein the assembly defines a first terminal and a second terminal opposing the first terminal in a direction along the longitudinal axis, and wherein the first terminal and the second terminal each have a respective width greater than the electron-transparent width.

4. The assembly of claim 3, wherein the first portion of the first conductive layer extends to the first terminal, and wherein the second portion of the first conductive layer extends to the second terminal.

5. The assembly of claim 1, wherein the first conductive layer comprises a first sublayer comprising Tantalum, a second sublayer comprising Ruthenium, and a third sublayer comprising Tantalum.

6. The assembly of claim 1, wherein the second conductive layer comprises Platinum.

7. The assembly of claim 1, wherein the insulating region is occupied by an insulating composition comprising carbon.

8. The assembly of claim 1, wherein the insulating region defines a wedge between the first portion and the second portion of the first conductive layer.

9. The assembly of claim 1, further comprising a device substrate.

10. The assembly of claim 1, further comprising a protective layer extending over the first portion of the first conductive layer and over the second conductive layer.

11. The assembly of claim 10, wherein the protective layer comprises carbon.

12. The assembly of claim 10, further comprising a third conductive layer at least partially extending over the protective layer, wherein the protective layer is between the nanoscale device and the third conductive layer.

13. The assembly of claim 12, wherein the third conductive layer defines an insulating gap separating the third conductive layer into a first portion and a second portion.

14. The assembly of claim 1, wherein the electron-transparent width is less than or equal to 70 nm.

15. The assembly of claim 1, further comprising the nanoscale device, wherein the nanoscale device comprises a magnetic tunnel junction (MTJ).

16. A method comprising:
operating a nanoscale device within an assembly, the assembly comprising:
a first conductive layer extending along a longitudinal axis, the first conductive layer comprising a first portion and a second portion laterally spaced from the first portion by an insulating region;
a second conductive layer extending along the longitudinal axis, the second conductive layer extending over the second portion and the insulating region; and
the nanoscale device at least partially contacting the first portion of the first conductive layer and at least partially contacting the second layer, at least a portion of the assembly defining an electron-transparent width in a direction transverse to the longitudinal axis; and
imaging the nanoscale device within the assembly during the operating to generate an image of the nanoscale device.

17. The method of claim 16, wherein the imaging comprises scanning transmission electron microscopy, and wherein the nanoscale device comprises a magnetic tunnel junction (MTJ).

18. The method of claim 16, wherein the image is a first image, and wherein the method further comprising:
after the imaging to generate the first image, changing a state of the nanoscale device from a first state to a second state; and
after changing the state of the nanoscale device, imaging the nanoscale device within the assembly to generate a second image of the nanoscale device.

19. The method of claim 18, further comprising comparing the first image and the second image to determine at least one difference in the nanoscale device between the first state and the second state,
wherein the first state is an operational state, and
wherein the second state is a breakdown state.

20. A method comprising:
forming a first conductive layer extending along a longitudinal axis, the first conductive layer comprising a first portion and a second portion laterally spaced from the first portion by an insulating region, the first portion of the first conductive layer at least partially contacting a nanoscale device; and
forming a second conductive layer extending along the longitudinal axis, the second conductive layer extending over the second portion and the insulating region, the second conductive layer at least partially contacting the nanoscale device;
wherein at least a portion of the assembly defines an electron-transparent width in a direction transverse to the longitudinal axis, and
wherein the insulating region comprises an insulating composition comprising carbon.
